(19) United States
(12) Patent Application Publication
(10) Pub. No.: US 2011/0139220 A1
(43) Pub. Date: Jun. 16, 2011

(54) SOLAR DEVICE AND SOLAR SYSTEM COMPRISING THE SAME

(75) Inventor: Ching-Yee Chak, Shatin (HK)

(73) Assignee: Du Pont Apollo Limited, Pak Shek Kok (HK)

(21) Appl. No.: 12/962,641

(22) Filed: Dec. 7, 2010

Related U.S. Application Data
(60) Provisional application No. 61/285,392, filed on Dec. 10, 2009.

(51) Int. Cl. H01L 31/0232; H01L 31/024; H01L 31/052

(52) U.S. Cl. 136/246; 136/259

(57) ABSTRACT

Disclosed herein is a prismatic solar device, which includes a triangular body, composed of a solar cell, a reflector and a decorating member. A triangular space is enclosed by the solar cell, reflector and decorating member. A solar system including a plurality of the solar devices is also disclosed.

### RELATED APPLICATIONS

This application claims priority to U.S. Provisional Application Ser. No. 61/285,392, filed Dec. 10, 2009, which is herein incorporated by reference.

### BACKGROUND

1. Field of Invention

The present invention relates to a photovoltaic device. More particularly, the present invention relates to a prismatic solar device.

2. Description of Related Art

Solar energy has gained many research attentions for an alternative cleaner and renewable energy source. For such purpose, different types of solar cell that convert solar energy directly into electrical energy are well developed.

Building integrated photovoltaics (BIPV) are photovoltaic materials that replace conventional building objects such as façades, rooftops or skylights. BIPV are often integrated with the building phase of the object, which means they are built or constructed along with the object, or planned together with the object so as to reduce the initial cost normally required to construct the part of the building that the BIPV modules replace. In addition, since BIPV are an integral part of the building, they are more aesthetical appealing than other solar options. These advantages make BIPV to be one of the fastest growing segments of the photovoltaic industry.

One of the BIPV examples is a “solar Venetian blind”, which integrates solar cells in a Venetian blind. In this example, solar cells are disposed on each of the slats of the Venetian blind. Wires are also disposed for transmitting the electricity generated by the solar cells to an external loading device. In addition, a stepper motor is employed to adjust the angle of each of the slats having solar cells thereon. The angle of each of the slats may be adjusted according to sunlight. However, this type of solar Venetian blinds may not achieve desirable photoelectrical conversion efficiency because a portion of light is reflected by the solar cell without being absorbed.

Therefore, there exists in this art a need of an improved solar device, which would achieve higher photoelectric conversion efficiency than the conventional device.

### SUMMARY

According to one aspect of the present disclosure, a prismatic solar device is provided. The prismatic solar device includes a triangular body composed of a first, second and third sides and enclose therein a triangular space, wherein the first, second and third sides are respectively a solar cell, a reflector and a decorating member.

In one embodiment of the present disclosure, prismatic solar device may optionally include a tube filled with coolant for keeping the prismatic solar device at a lower temperature.

According to another aspect of the present disclosure, a solar system is provided. The solar system includes a plurality of prismatic solar devices described herein and a driving member. The driving member is operable to adjust the positions of the at least two prismatic solar devices simultaneously, such that the solar cells are positioned to receive a maximum light exposure at day time. The reflectors are positioned to reflect light back to the adjacent solar cells positioned above, and the decorating members are positioned to display a pattern.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a perspective view of a solar system according to one embodiment of the present disclosure;

FIG. 2 is a perspective view of a prismatic solar device according to one embodiment of the present disclosure;

FIG. 3 schematically illustrates the optical path of a solar system according to one embodiment of the present disclosure; and

FIG. 4 schematically illustrates the optical path of a solar system according to one embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

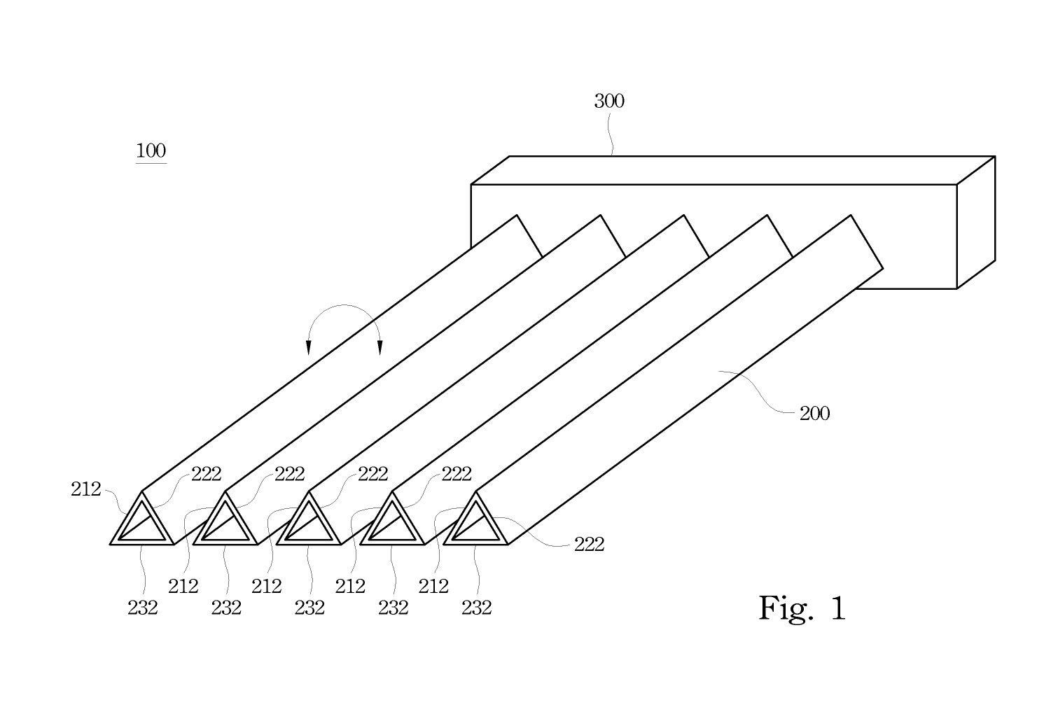

FIG. 1 is a perspective view of a solar system 100 according to one embodiment of the present disclosure. As depicted in FIG. 1, the solar system 100 includes a plurality of prismatic solar devices 200 and a driving member 300. The prismatic solar devices 200 are arranged in parallel, and each of the prismatic solar devices 200 may extend along a horizontal direction or vertical direction. In this embodiment, each of the prismatic solar devices 200 has a triangular prismatic body, but not to limit the scope of the present invention. For example, the prismatic solar devices 200 may include equilateral or polygon prismatic body. The driving member 300 is operable to drive each of the prismatic solar devices 200 to turn continuously, or each time in 3 degrees.

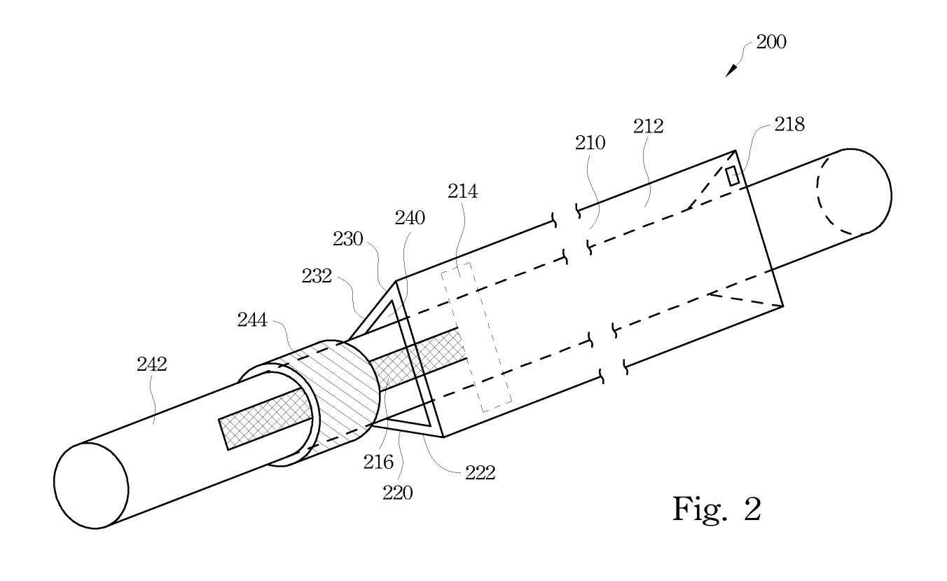

FIG. 2 is a perspective view of a prismatic solar device 200 according to one embodiment of the present disclosure. As depicted in FIG. 2, the prismatic solar device 200 is composed of a first side 210, second side 220 and third side 230.

Furthermore, the first, second and third sides enclose a triangular space 240 therein. In one example, the first, second and third sides are a solar cell 212, a reflector 222 and a decorating member 232 respectively.

The solar cell 212 is capable of converting light into electricity. There is no specific limitation on the solar cell 212 so long as it may convert light into electricity. In one example, the solar cell 212 is a thin film solar cell, which is integrated on a glass substrate. In other examples, the solar cell 212 may be a single crystal solar cell or a polycrystalline solar cell, which is formed on a silicon substrate. For increasing the photoelectric conversion efficiency of the solar cell 212, pyramid-like structures or textured structures (not shown) may be formed on the surface of solar cell 212, which is known in the art.

The reflector 222 is operable to reflect light. In some examples, the reflector 222 may be a flat and high reflective sheet made of aluminum, silver, copper, chromium or nickel.

The decorating member 232 may be provided as a displaying element or as part of a decoration. In one example, the decorating member 232 may include a flat panel and a colorful picture forms thereon. In another example, the decorating member 232 may comprise LEDs for displaying a colorful pattern.

In one embodiment, as depicted in FIG. 2, a tube 242 filled with a coolant may be arranged in the triangular space 240 for keeping the temperature of the prismatic solar device 200 at a lower temperature, such as at 25° C.-50° C. The photoelectric conversion efficiency of the solar cell 212 decreases as the temperature increases. The coolant in the tube may prevent the solar cell 212 from overheating. For this purpose, the tube 242 may be made of a material having a high thermal conductivity. Suitable coolants include, but are not limited to, water, ethylene glycol or diethylene glycol. The heat accumulated in the prismatic solar devices 200 may be transferred away by the coolant flowing through the tube 242 for other purposes such as indoor warming. Thus, the prismatic solar devices 200 could be kept at a lower temperature around 25° C.-50° C. Therefore, the photoelectric conversion efficiency of the solar cell 212 may be kept at a normal level.

While water is adopted as a coolant, the water that flows out of the tube 242 has a temperature higher than the ambient temperature, and may be further employed in daily consumption.

In another embodiment, each of the prismatic solar devices 200 may further include a first electrical conductive ribbon 214 and a second electrical conductive ribbon 216 as shown in FIG. 2. The first electrical conductive ribbon 214 is electrically connected to the solar cell 212 and it is capable of collecting and transmitting the electric energy generated by the solar cell 212. In one example, the first electrical conductive ribbon 214 is arranged in the triangular space 240 of the prismatic solar device 200 to prevent the solar cell 212 from being shielded. For instance, the first electrical conductive ribbon 214 may be disposed at the backside of the solar cell 212. Further, the second electrical conductive ribbon 216 is electrically connected to the first electrical conductive ribbon 214 and extends out of the prismatic solar device 200 for connecting to an external loading device (not shown). In another example, an electrical conductive ring 244 surrounding the tube 242 may optionally be arranged. In this case, the second electrical conductive ribbon 216 may contact with the electrical conductive ring 244 and electrically connect to an external loading device through the electrical conductive ring 244. In this example, while the prismatic solar device 200 revolves about the axis of the tube 242, the electric energy generated by the solar cell 212 may also be transmitted to the external loading device through output terminal cables connected within a junction box.

In still another embodiment, the prismatic solar device 200 may further include a photo sensor 218 disposed on an external surface of the solar cell 212 as depicted in FIG. 2. In one example, the photo sensor 218 is operable to detect the irradiance of light projecting on the solar cell 212. In another example, the photo sensor 218 is also capable of detecting the position of the sun. In these examples, a processor or controller (not shown) may be employed to receive the signal from the photo sensor 218, and the signal may further be used to control the position or rotation of the prismatic solar device 200 to the desired position. More specifically, the prismatic solar device 200 may be rotated about the axis of the tube 242 according to the detected signal.

Referring back to FIG. 1, the plurality of the prismatic solar devices 200 are arranged in parallel with all solar cells 212 of the prismatic solar devices 200 facing one direction and all reflectors 222 of the prismatic solar devices 200 facing another direction. Each of the prismatic solar devices 200 may be rotated individually by the driving member 300. Alternatively, all the prismatic solar devices 200 may be rotated together by the driving member 300 according to the demands. The driving member 300 may drive each of the prismatic solar devices 200 to turn continuously, or each time in 3 degrees. In one example, the driving member 300 may comprise an AC motor or a DC motor.

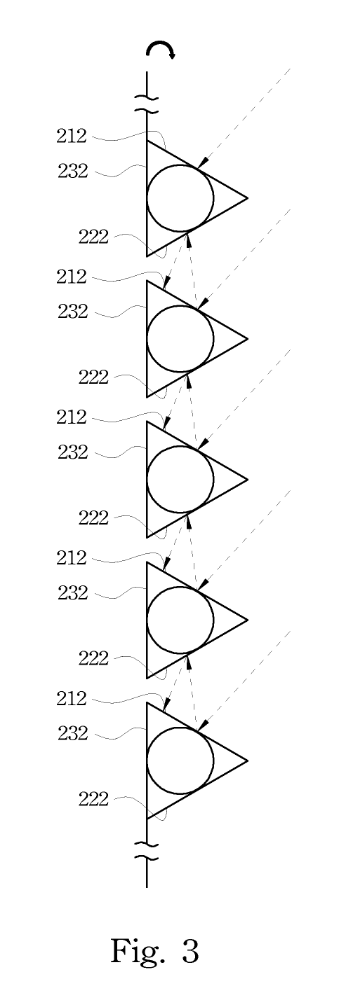

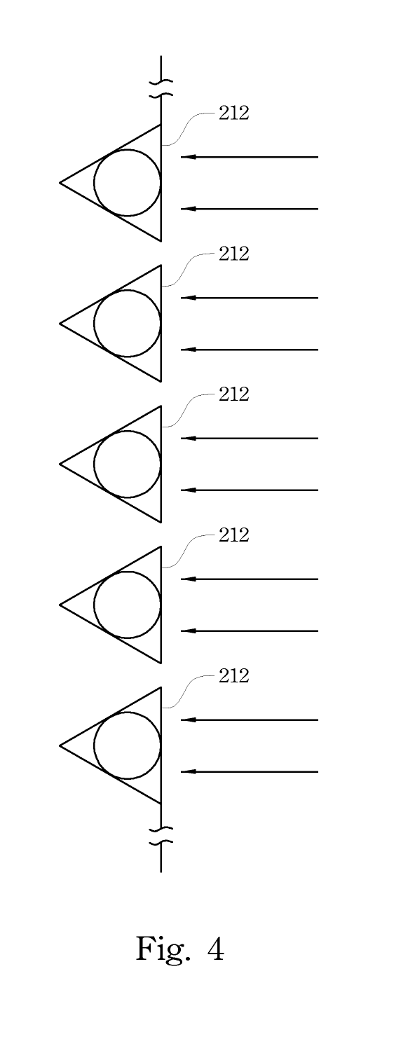

FIG. 3 is schematically illustrated the optical path of a solar system 100 according to one embodiment of the present disclosure. In daytime, each of the solar cells 212 on the prismatic solar devices 200 faces and receives sunlight. When light is projected on the solar cell 212, a portion of the light may be transmitted into the solar cell 212 and be converted into electricity. However, a portion of the light may be reflected by the surface of solar cell 212 and exits the solar cell 212 without light absorption. This escaped light that is reflected from one of the solar cell 212 may be reflected back into another adjacent solar cell 212 by another reflector 222 located at a prismatic solar device 200 disposed above. Therefore, light may be reflected between the solar cell 212 on one prismatic solar device 200 and the reflector 222 located on another neighboring prismatic solar device 200, particularly, the one above, thereby increasing the light absorption. Each of the prismatic solar devices 200 may be rotated to ensure that the entire solar system 100 would receive a maximum light exposure. As a result, the photoelectric conversion efficiency of solar system 100 may be further increased. As depicted in FIG. 4, each of the solar cells 212 may be rotated to face the sunlight directly if the sunlight may project on the solar system 100 at a normal angle.

In one example, the solar system 100 may be as applied to a Venetian blind, which is setting in a room or utilized as BIPV. In daytime, the plurality of the solar cells 212 of the prismatic solar devices 200 may be positioned to receive sunlight and convert it into electricity. At night, the decorating members 232 of the prismatic solar devices 200 may be positioned towards either indoor or outdoor to be the part of a decoration. While the decorating members 232 comprise LEDs, the solar system 100 may display a colorful pattern.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A prismatic solar device comprising:
a triangular body composed of a first, second and third sides and enclose therein a triangular space, wherein the first, second and third sides are respectively a solar cell, a reflector and a decorating member, wherein the solar cell has a back surface adjacent to the triangular space and a front surface for receiving light.

2. The prismatic solar device according to claim 1, further comprising a first electrical conductive ribbon for collecting an electrical energy generated by the solar cell, wherein the first electrical conductive ribbon is disposed on the back surface of the solar cell.

3. The prismatic solar device according to claim 2, further comprising a second electrical conductive ribbon, wherein the second conductive ribbon is electrically connected to the first electrical conductive ribbon and extends out of the prismatic solar device.

4. The prismatic solar device according to claim 1, further comprising a tube disposed inside the triangular space.

5. The prismatic solar device according to claim 4, wherein the tube comprises a coolant flowing through.

6. The prismatic solar device according to claim 5, wherein the coolant comprises a material selected from the group consisting of water, ethylene glycol and diethylene glycol.

7. The prismatic solar device according to claim 1, wherein the reflector comprises aluminum, silver, copper, chromium or nickel.

8. The prismatic solar device according to claim 1, wherein the decorating member comprises a flat panel and a colorful picture formed thereon.

9. The prismatic solar device according to claim 1, wherein the decorating member comprises a LED for displaying a colorful pattern.

10. The prismatic solar device according to claim 1, further comprising a photo sensor disposed on an external surface of the solar cell.

11. A solar system, comprising:
a plurality of prismatic solar devices according to claim 1 arranged in parallel; and
a driving member for adjusting the positions of the prismatic solar devices simultaneously, such that the solar cells are positioned to receive a maximum light exposure at day time, the reflectors are positioned to reflect light back to adjacent solar cells, and the decorating members are positioned to display a pattern.

12. The solar system of claim 11, wherein the driving member comprises an AC motor or a DC motor.
